(19) United States
(12) Patent Application Publication
(10) Pub. No.: US 2015/0146287 A1
(43) Pub. Date: May 28, 2015

(54) MULTILAYER STRUCTURE AS REFLECTOR

(71) Applicant: Bayer Material Science AG, Leverkusen (DE)

(72) Inventors: Timo Kuhlmann, Leichlingen (DE); Rafael Oser, Krefeld (DE)

(73) Assignee: BAYER MATERIALSCIENCE AG, LEVERKUSEN (DE)

(21) Appl. No.: 14/402,437

(22) PCT Filed: May 27, 2013
(86) PCT No.: PCT/EP2013/060822

§ 371 Date: Nov. 20, 2014

(30) Foreign Application Priority Data
Jun. 1, 2012 (EP) 12170439.9

(51) Int. Cl. G02B 5/08; B32B 37/12; C23C 14/14

(52) U.S. Cl. CPC G02B 5/0808; G02B 5/0891; C23C 14/14; B32B 37/12
USPC 359/360; 427/162; 156/60

(57) ABSTRACT

The present invention relates to a multilayer structure comprising A) a functional film comprising a VIS/IR-reflecting metal layer on a carrier film, wherein the carrier film can be in single-layer form or in the form of a UV- and/or UV/VIS-reflecting multi-ply layer, and at least one adhesive layer, and optionally at least one scratch-resistant layer, B) a functional layer comprising a layer of metal nitrides, metal oxides or semimetal oxides, mixed oxides or metals, wherein the layer can additionally have a coating, C) optionally a carrier film, D) optionally an adhesive layer, E) a substrate layer. By means of such a multilayer structure it is possible, in the adhesive bonding of thin functional films by means of a PSA (“pressure sensitive adhesive”) to thermoplastics such as, for example, polycarbonate, largely to avoid blistering of the adhesively bonded film in the case of outside use (in a changing climate).

The present invention relates to a multilayer structure comprising a plurality of layers having improved adhesion properties for use as a mirror, for example within the CPV (concentrating photovoltaics) and CSP (concentrating solar power) fields, within lighting systems and also for mirrors and reflectors for inside and outside use. The multilayer structure comprises (from bottom to top) at least one substrate layer, a metal-comprising layer and a reflective functional film. The invention relates further to a process for the production thereof and to an advantageous use.

JP 2012-037634 A describes a multilayer film which reflects solar radiation and comprises as carrier film a polyester film comprising a specific sequence of five superposed layers (ZnO/Ag/ZnO/Ag/ZnO) for obtaining a reflective layer having good optical properties. This document relates to different metal oxide layers for protecting the reflective layer Ag in comparison with known metal oxide layers (e.g. titanium dioxide) for protecting Ag.

WO2009/114493 describes a specific mirror structure on glass as substrate which is to provide specific metal oxide layers for protecting the reflective silver layer at high production temperatures. The adhesive layer described in this document is an adhesion-promoting layer and not an adhesive layer as in the present application. When thin functional films are adhesively bonded by means of a PSA (“pressure sensitive adhesive”) to thermoplastics such as, for example, polycarbonate, unacceptable blistering is observed on the adhesively bonded film after a short time when used outside (in a changing climate). The functionality of the adhesively bonded functional film can thereby be impaired, which is undesirable in particular in the case of applications in the CPV (concentrating photovoltaics) and CSP (concentrating solar power) fields.

There is no suitable alternative adhesive for adhesively bonding the functional film to the thermoplastic because, when a PSA is used, the functional film adhesively bonded to the thermoplastic can be replaced if required.

The object of the present invention is, therefore, to avoid the above-described blistering of the laminate when used outside and accordingly maintain the functionality of the laminate in the long term.

The object is achieved according to the invention by a multilayer structure comprising
A) a functional film comprising a VIS/IR-reflecting metal layer on a carrier film, wherein the carrier film can be in single-layer form or in the form of a UV- and/or UV/VIS-reflecting multi-ply layer, and at least one adhesive layer, wherein the adhesive layer is a pressure sensitive adhesive, and optionally at least one scratch-resistant layer,
B) a functional layer comprising a layer of metal nitrides, metal oxides or semimetal oxides, mixed oxides or metals, wherein the layer can additionally have a coating,
C) optionally a carrier film,
D) optionally an adhesive layer,
E) a thermoplastic substrate layer.

Surprisingly, it has been found that the above-described blistering can be avoided by means of a specific surface modification of the thermoplastic substrate, in particular polycarbonate. The specific surface modification consists in depositing a metal oxide or semimetal oxide layer, such as, for example, an SiO₂ layer. Surprisingly, not every metal oxide or semimetal oxide layer is suitable for adhesion promotion. For example, SiO₂ layers which have been produced by a sol-gel process and applied to the substrate are not suitable for preventing blistering. By contrast, SiO₂ layers according to the invention which have been applied by a PVD (physical vapour deposition) process or CVD (chemical vapour deposition) process exhibit an adequate ability to prevent blistering. Metal oxide layers (such as Al₂O₃) which have been deposited by the PVD process are likewise suitable. Some metal layers, such as, for example, aluminium, are also suitable. However, the susceptibility of the metal to corrosion when used outside is to be taken into consideration. Tarnishing of aluminium, for example, is thus to be observed in this application.

An embodiment of the invention is further a multilayer structure according to the present invention in which the functional layer B) is located on a carrier film C).

The deposition of the functional layer B on a carrier film C) and the subsequent joining of the film of B) and C) so obtained by means of an adhesive layer D) to a polycarbonate substrate E) likewise leads to a surface modification according to the invention and is provided by the present invention.

The present invention further provides a process for the production of a multilayer structure comprising layers A) to E), in which
a) layers A) and B) and C) are applied by means of an adhesive layer D) to the substrate layer E), or
b) layer B) is applied to a carrier film C), the film so obtained is applied by means of an adhesive layer D) to a substrate layer E), and layer A) is then applied.

The individual layers can be formed as follows:

### Layer A)

Preferred thermoplastic plastics for the carrier film of layer A) in the case of a single-layer form are polycarbonate, copolycarbonates, polyester carbonates, polystyrene, styrene copolymers, aromatic polyesters such as polyethylene terephthalate (PET), PET-cyclohexanedimethanol copolymer (PETG), polyethylene naphthalate (PEN), polybutylene terephthalate (PBT), aliphatic polyolefins such as polypropylene or polyethylene, cyclic polyolefin, poly- or copoly-acrylates and poly- or copoly-methacrylate such as, for example, poly- or copoly-methyl methacrylates (such as PMMA) and also copolymers with styrene such as, for example, transparent polystyrene-acrylonitrile (PSAN), thermoplastic polyurethanes, polymers based on cyclic olefins (e.g. TOPAS®, a commercial product from Ticona), polycarbonate blends with olefinic copolymers or graft polymers, such as, for example, styrene/acrylonitrile copolymers.

Particularly preferred as the material for the carrier film are PMMA, PET, PEN, PETG, polycarbonate and copolycarbonate, and PMMA, PET or PEN are most particularly preferred. PET is most particularly preferred.

The above-mentioned polymers can be used on their own or in mixtures.

If the carrier film is the UV- and/or UV/VIS-reflecting multi-ply layer, then the following material combinations can be used in an alternating sequence as the optically active layers. There are preferably used layer combinations consisting of PET (polyethylene terephthalate) and THV (tetrafluoroethylene hexafluoropropylene vinylidene fluoride), of PET and OTP (polydiorganosiloxane polyoxamide block copolymers), of PEN and THV, of PEN and OTP, of PEN and PMMA, of PET and coPMMA, of PEN and coPMMA layer pairs, of coPEN and PMMA layer pairs, of coPEN and OTP, of coPEN and THV, of sPS (syndiotactic polystyrene) and OTP, of sPS and THV, of PMMA and THV, of COC and THV, or of EVA layer and THV pairs.

Such reflective multi-ply layers are known and are described inter alia in U.S. Pat. No. 3,610,724, U.S. Pat. No. 3,711,176, U.S. Pat. No. 4,446,305, U.S. Pat. No. 4,540,623, U.S. Pat. No. 5,448,404, U.S. Pat. No. 5,882,774, U.S. Pat. No. 6,045,894, U.S. Pat. No. 6,531,230, WO 99/39224, US 2001/0022982 A1.

The VIS/IR-reflecting metal layer can comprise any metal or any metal combination that efficiently reflects VIS/IR radiation. In general, the metal layer should be about 100 nm thick in order to ensure a high reflecting capacity. Preferred metals are silver, copper, aluminium, copper on silver, nickel-chromium, stainless steel and/or nickel or combinations thereof. Combinations comprising silver are particularly preferred.

In a preferred embodiment, the silver layer is surrounded on one side by an aluminium layer and on the other side by a copper layer.

The metal layer or the metal layers can be joined to the carrier film or to the UV- and/or UV/VIS-reflecting multi-ply layer by any suitable technique including lamination, sputtering and vapour deposition.

Layer systems A) comprising a carrier film or a UV- and/or UV/VIS-reflecting multi-ply layer as the carrier film combined with a VIS/IR-reflecting metal layer are also referred to as broadband reflectors.

In some embodiments, the broadband reflector has a mean light-reflecting capacity of at least 95 percent in a wavelength range of from 350 to 400 nanometres.

In some embodiments, the broadband reflector has a mean light-reflecting capacity of at least 90 percent in a wavelength range of from 300 to 2494 nanometres.

Suitable adhesives which can be used in the production of broadband reflectors and also as the adhesive layer of layer A) according to the present invention are optically transparent and suitably stable to UV light or not.

So-called PSAs, pressure sensitive adhesives, are used as adhesives. PSAs are understood as being adhesives which are already permanently adhesive at room temperature and exhibit intimate adhesion to other surfaces. This adhesion occurs with the exertion of only a slight pressure, as can be exerted, for example, by the force of a finger.

Compound classes for PSAs are, for example, acrylates, polyurethanes, polyalphaolefins, silicones, or tackified natural or synthetic rubber.

Tackified OTP, as described in U.S. Pat. No. 7,371,464 B2 (Sherman et al.), can also be used as the adhesive.

Further preferred adhesives are “non-silicone-based adhesives”, which have been described inter alia in W02009085662A2 having the title “Urea-Based Pressure Sensitive Adhesives” and in US20120100326A1 having the title “Urethane-Based Pressure Sensitive Adhesives”.

For structures that are not sensitive to light, any desired adhesive composition, for example an epoxy, urethane, silicone or acrylic adhesive or a combination thereof, can be used.

Preference is given within the scope of the invention to adhesives from the class of the optically clear pressure-sensitive acrylic adhesives.

Commercially available acrylic adhesives are LAMINATING ADHESIVE 8141 or LAMINATING ADHESIVE 8171, 8172 and 8173D from 3M.

The adhesive composition can be, for example, an adhesion promoter, a heat-curing adhesive, a hot melt adhesive, or a combination thereof.

Layer A) can be terminated at the interface with the outside environment by a scratch-resistant layer. This can in principle be any wear-resistant material which is permeable to the reflected wavelengths of the broadband reflector.

In one embodiment, the scratch-resistant layer consists of a thermoplastic urethane (trade name Tecoflex) from Lubrizol Advanced Materials Inc. comprising 5 wt. % Tinuvin 405, 2 wt. % Tinuvin 123 and 3 wt. % Tinuvin 1577, in each case from BASF SE.

In one embodiment, the scratch-resistant layer consists of a heat-curable and silicone-based polymer composition (trade name PERMA-NEW 6000 (or PERMA-NEW 6000B) CLEAR HARD COATING SOLUTION) from California Hardcoating Co.

The scratch-resistant layer can have any desired thickness, depending on the material used. Typical layer thicknesses are approximately from 1 micrometre to 10 micrometres, preferably from 3 micrometres to 6 micrometres.

The scratch-resistant layer can optionally comprise a dirt-repellent component. Examples of dirt-repellent components include fluoropolymers, silicone polymers, and titanium dioxide particles, fluoropolymers, silicone polymers, titanium dioxide particles, polyhedral oligomeric silsesquioxanes (e.g. POSS from Hybrid Plastics) and combinations thereof.

In further embodiments of the scratch-resistant coatings are heat-curing coating systems based on a polysiloxane lacquer, which can be both single-layer and multilayer (with a merely adhesion-promoting primer layer between the substrate and the polysiloxane topcoat). These are described inter alia in U.S. Pat. No. 4,278,804, U.S. Pat. No. 4,373,061, U.S. Pat. No. 4,410,594, U.S. Pat. No. 5,041,313 and EP-A-1 087 001. Examples which may be mentioned here are the commercially available systems from Momentive Performance Materials Inc. Wilton, Conn. USA such as PHC 587; PHC 587B, PHC 587C; SHP 401 (primer)/AS 4000 (topcoat) or also SHP 401 (primer)/AS 4002 (topcoat), as well as KASI Flex® or Sun Flex®, both from KRD Coatings, Geesthacht, Germany, or Silvue® MP 100, SDC Coatings, Germany, or Sicralan® MRL from GFO, Schwabisch GmUnd, Germany.

In further embodiments of the scratch-resistant coatings are heat-curing multilayer systems having an anti-UV primer and a topcoat based on a polysiloxane lacquer. Suitable systems are known, for example, from U.S. Pat. No. 5,391,795 and U.S. Pat. No. 5,679,820 and “Paint & Coating Industrie; July 2001 pages 64 to 76: The Next Generation in Weatherable Hardcoats for Polycarbonate” by George Medford/General Electric Silicones, LLC, Waterford, N.Y.; James Pickett/The General Electric Co., Corporate Research and Development, Schenectady, N.Y.; and Curt Reynolds/Lexamar Corp., Boyne City, Mich. A commercially available system is the SHP470 (anti-UV primer) or SHP470FT (anti-UV primer)/AS4700 (topcoat) system from Momentive Performance Materials mentioned therein. This SHP470 or SHP470FT is an adhesion-promoting anti-UV primer based on polymethyl methacrylate inter alia with 1-methoxy-2-propanol and diacetone alcohol as solvent and dibenzoyl resorcinol as UV absorber. The AS4700 topcoat is a polysiloxane topcoat with silylated UV absorber.

In further embodiments, UV-curing coating systems, for example based on acrylate, urethane acrylate or acrylsilane, which optionally comprise fillers for improving the scratch resistance, can form adequate weather protection and scratch protection on account of their greater application layer thickness window. Such systems are known and are described inter alia in U.S. Pat. No. 3,707,397 or DE 69 71 7959, U.S. Pat. No. 5,990,188, U.S. Pat. No. 5,817,715 and U.S. Pat. No. 5,712,325. Examples of such a suitable coating are the commercially available UVHC 3000, UVHC 3000K and UVHC 3000S systems from Momentive Performance Materials or UVT 200 and UVT 610 from Redspot.

In all the above-mentioned scratch-resistant coatings, the proportion of the light stabiliser(s), UV absorber(s) and/or radical acceptor(s) is to be so chosen that no undesirable effect occurs as regards the reflection of the UV-, UV/VIS- and/or VIS/IR-reflecting layers.

Above-described functional films are known and are described, for example, in WO 2010/078105. Such functional films are available commercially under the following trade names: Reflectech® Mirror Film from Reflectech or Silver Reflector from Southwall or Solar Mirror Film 1100 (SMF1100) from 3M.

### Layer B)

Layer B) provided according to the invention comprises at least one metal layer, metal oxide or semimetal oxide layer, metal nitride layer or mixed oxide layer.

The metals, metal oxides or semimetal oxides, metal nitrides and mixed oxides are selected from aluminium, copper, silver, titanium, chromium, chromium alloys, stainless steel, gold, platinum, aluminium oxide, titanium dioxide, silicon oxide SiOₓ, tantalum pentoxide Ta₂O₅, zirconium oxide, zirconium dioxide, Nb₂O₅, HfO, zinc-tin oxide, indium-tin oxide, aluminium-zinc oxide, silicon nitride, boron nitride or titanium nitride. Preferred layer materials are selected from aluminium, stainless steel, copper, titanium, aluminium oxide, silicon oxide SiOₓ, silicon nitride or zinc-tin oxide.

The layer thicknesses are from 5 nm to 300 nm, preferably from 10 nm to 200 nm, particularly preferably from 20 nm to 180 nm.

Above and/or below the metal layer, metal oxide or semimetal oxide layer, metal nitride layer or mixed oxide layer there can be one or more coating layers.

Furthermore, the metal layer, metal oxide or semimetal oxide layer, metal nitride layer or mixed oxide layer, on the one hand, and the coating layers, on the other hand, can be arranged alternately.

Examples which explain such multilayer concepts in greater detail, without implying any limitation, are patents EP2272928A1, EP792846A1, US20030077462, EP2268390A1, EP1217052A2, W02010127808A1 and W02007051860A1 and citations contained therein.

### Application of Layer B)

The layers B) are applied either by a PVD process or by a CVD process to layer C) or layer E). The processes are described in greater detail, for example, in “Vakuumbeschichtung Vol. 1 to 5”, H. Frey, VDI-Verlag DÜsseldorf 1995 or “Oberflächen- and DÜnnschicht-Technologie” Part 1, R. A. Haefer, Springer Verlag 1987. Further processes are described inter alia in Surface and Coatings Technology 111 (1999), 287-296.

In order to achieve better metal adhesion and in order to clean the substrate surface, the substrates are normally subjected to a plasma pretreatment. A plasma pretreatment can in some cases change the surface properties of polymers. These methods are described, for example, in Friedrich et al. in Metallized plastics 5 & 6: Fundamental and applied aspects and H. GrÜnwald et al. in Surface and Coatings Technology 111 (1999) 287-296.

### Layer C)

Above-mentioned layers B) can also be deposited on a carrier film (layer C)) which is selected from a thermoplastic plastic.

Preferred thermoplastic plastics for layer C) are polycarbonate, copolycarbonate, polyester carbonate, polystyrene, styrene copolymers, aromatic polyesters such as polyethylene terephthalate (PET), PET-cyclohexanedimethanol copolymer (PETG), polyethylene naphthalate (PEN), polybutylene terephthalate (PBT), aliphatic polyolefins such as polypropylene or polyethylene, cyclic polyolefin, poly- or copoly-acrylates and poly- or copoly-methacrylate such as, for example, poly- or copoly-methyl methacrylates (such as PMMA) and also copolymers with styrene such as, for example, transparent polystyrene-acrylonitrile (PSAN), thermoplastic polyurethanes, polymers based on cyclic olefins (e.g. TOPAS®, a commercial product from Ticona), polycarbonate blends with olefinic copolymers or graft polymers, such as, for example, styrene/acrylonitrile copolymers.

PMMA, PET, PEN, PETG, polycarbonate, copolycarbonate or polyester carbonate is particularly preferred. PMMA, PET or PEN is most particularly preferred. The above-mentioned polymers can be used on their own or in mixtures.

Preferred film thicknesses of the thermoplastic layer C) are from 10 μm to 500 μm. Particularly preferred film thicknesses are from 20 μm to 250 μm. Films having a thickness of from 25 μm to 125 μm are particularly preferred as carrier material.

### Layer D)

A suitable adhesive of layer D) is a 2-component adhesive, which consists of two different components which are able to react with one another to form a crosslinked adhesive film. In particular, they are 2K polyurethane adhesives which crosslink via NCO groups and constituents containing acidic H groups. Examples thereof comprise as component A the known NCO-group-containing prepolymers or polyisocyanates, and there can be used as component B the known OH—, NH—, SH—, COOH-group-containing oligomers or polymers, which are able to react with the NCO groups of the other component. In order to obtain a network, it is advantageous if at least two NCO groups and at least two in particular OH groups are contained in the crosslinking constituents. Furthermore, additives known per se can be present in the adhesive. These are constituents with which particular properties of the adhesive can be established and influenced.

For example, there is used as component A a PU prepolymer carrying at least two isocyanate groups, or a mixture of such PU prepolymers, which is obtainable, for example, by reacting a polyol component with an at least difunctional isocyanate in stoichiometric excess.

PU prepolymers within the meaning of the present invention are reaction products of OH-group- or NH-group-carrying compounds with an excess of polyisocyanates. They are the polyols known for adhesive use or corresponding compounds having secondary and/or primary amino groups. OH-containing starting compounds are preferred. Particularly suitable for the synthesis of such prepolymers are polyols having a molecular weight of up to 20,000 g/mol, in particular from 200 to 10,000 g/mol (number-average molecular weight, MN, as can be determined by GPC). They can be, for example, polyols based on polyethers, polyesters, polyolefins, polyacrylates, alkylene polyols. In another embodiment, such compounds having NH groups are used.

The polyol component can be of low molecular weight, for example approximately from 60 g/mol to 1500 g/mol, but higher molecular weight polymers can also be reacted, for example those having a molecular weight of from 1500 to 20,000 g/mol. On average two reactive groups are to be present in the polyol, for example diols; it is also possible to react compounds having a plurality of functional groups.

One embodiment preferably uses low molecular weight unbranched polyols which have a molecular weight of below 1500 g/mol, wherein these polyols are to have 3 or in particular 2 OH groups. Another embodiment uses OH-containing polymers having a molecular weight of up to 20,000 g/mol. A higher number of OH groups can also be present.

There can be used as polyisocyanates in the prepolymer synthesis the polyisocyanates known per se having two or more isocyanate groups, such as aliphatic, cycloaliphatic or aromatic isocyanates. All known polyisocyanates can in principle be used, in particular the isomers of methylene diisocyanate (MDI) or toluene diisocyanate (TDI), tetramethylxylylene diisocyanate (TMXDI), 1-isocyanatomethyl-3-isocyanato-1,5,5-trimethylcyclohexane (IPDI), naphthalene 1,5-diisocyanate (NDI), hexane 1,6-diisocyanate (HDI). It is also possible to use isocyanates having a functionality of at least three, as are obtained by trimerisation or oligomerisation of diisocyanates, such as isocyanurates, carbodiimides or biurets. Diisocyanates, in particular aromatic diisocyanates, are preferably used.

The reaction procedure can be influenced by the amount of isocyanates. If a high excess of isocyanates is used, PU prepolymers in which the OH groups have been functionalised into isocyanate groups are obtained. Only a slight molecular weight build-up is thereby noted. If smaller amounts of isocyanates are used, or if the reaction is carried out stepwise, it is known that the molecular weight of the prepolymers is increased in comparison with the starting compounds. It must be ensured that an excess of isocyanate groups is used in total, based on the reaction as a whole. The reaction of the polyol compound with the isocyanates can be carried out in a known manner.

For the invention, the known PU prepolymers having reactive NCO groups can be used. These are known to the person skilled in the art and can also be obtained commercially. Particular preference is given within the scope of this invention to PU prepolymers which have been prepared on the basis of polyester polyols or polyether polyols by reaction with diisocyanates. Generally, the PU prepolymers used within the scope of the present invention have a molecular weight of from 500 to approximately 30,000 g/mol, preferably up to 15,000 g/mol, in particular from 1000 to 5000 g/mol. Preference is given to prepolymers that contain only a small proportion of monomeric, unreacted diisocyanates, for example less than 1 wt. %.

Another embodiment uses as component A monomeric, oligomeric or polymeric isocyanates. They can be, for example, the above-mentioned polyisocyanates or their carbodiimides, isocyanurates or biurets. Mixtures of prepolymers and polyisocyanates are also possible.

In addition to the suitable constituents having NCO groups, component A can also comprise further auxiliary substances and additives. It must be ensured that only constituents that are not able to react with the isocyanate groups are added. Storage stability can thus be ensured.

Component B of a suitable 2K PU adhesive must comprise at least one compound which has at least two groups that are reactive towards isocyanate groups. Such groups can be, for example, SH, COOH, NH or OH groups. Particular preference is given to polyols, which can also be mixtures of polyols of different chemical structures or different molecular weights.

A large number of polyols are suitable as the polyol component for use in component B. They can be, for example, polyols having from two to 10 OH groups per molecule. They can be aliphatic compounds, they can be aromatic compounds, it is also possible to use polymers which carry a sufficient number of OH groups. They can be primary or secondary OH groups, provided that there is sufficient reactivity with the isocyanate groups. The molecular weight of such polyols can vary within wide limits, for example can be from 500 to 10,000 g/mol. The polyols already described above can be present.

Examples of such polyols are low molecular weight aliphatic polyols having preferably from two to ten OH groups, in particular C2- to C36-alcohols. Another group of suitable polyols are, for example, polyethers. These are the reaction products of alkylene oxides having from 2 to 4 carbon atoms with low molecular weight alcohols having a functionality of 2 or 3. The polyether polyols are to have a molecular weight of in particular from 400 to 5000 g/mol. OH-containing poly(meth)acrylates or polyolefins are also suitable.

A further suitable group of polyol compounds for use in component B are polyester polyols. The polyester polyols known for adhesives can be used. For example, they are the reaction products of diols, in particular low molecular weight alkylene diols or polyether diols, with dicarboxylic acids. They can be aliphatic, aromatic carboxylic acids or mixtures thereof. Such polyester polyols are known to the person skilled in the art in many forms and are available commercially. In particular, the polyester polyols are to have a molecular weight of in particular from 200 to 3000 g/mol. They are also to be understood as including polymeric lactones or polyacetals, provided that they have at least two functional groups and a corresponding suitable molecular weight.

The suitable polyols which have at least two reactive groups can be used individually or in a mixture. It is to be ensured that the compounds are miscible with one another, and that phase separation does not occur when they are stored. The viscosity can be influenced by the choice of the constituents of component B. If polymeric polyols are used, component B has a higher viscosity. When proportions of low molecular weight polyols are used, for example polyalkylene polyols having up to 12 carbon atoms, the viscosity will become lower. It is advantageous if component B is liquid. This can be achieved by the choice of the polyols, but in another embodiment it is possible to add inert organic solvents.

2K laminating adhesives can be prepared from the above-described binder components. It can be advantageous for additional constituents to be present in these laminating adhesives, such as, for example, solvents, plasticisers, catalysts, resins, stabilisers, adhesion promoters, pigments or fillers.

In one embodiment, the suitable adhesive comprises at last one tackifying resin. All resins that are compatible and form a largely homogeneous mixture can in principle be used. Suitable stabilisers or antioxidants which can optionally be used are sterically hindered phenols of high molecular weight, polyfunctional phenols, sulfur- and phosphorus-containing phenols or amines.

It is possible additionally to add to the adhesive silane compounds as adhesion promoters. There can be used as adhesion promoters the known organofunctional silanes, such as (meth)acryloxy-functional, epoxy-functional, amine-functional or non-reactively substituted silanes; methoxy- or ethoxy-silane groups are particularly suitable.

An adhesive that is used can also comprise catalysts as an additive that is additionally present. All known compounds that are able to catalyse the reaction of OH group and NCO group can be used as catalysts. Examples thereof are titanates, tin carboxylates, tin oxides, organoaluminium compounds, tert-amine compounds or their salts. Suitable additives are known to the person skilled in the art.

Other embodiments also comprise pigments in the adhesive. These are finely divided pigments, for example plate-like or nanoparticles. Plasticisers can also be present, for example white oils, naphthenic mineral oils, paraffinic hydrocarbon oils, polypropylene, polybutene, polyisoprene oligomers, hydrogenated polyisoprene and/or polybutadiene oligomers, phthalates, adipates, benzoate esters, vegetable or animal oils and their derivatives. Particularly suitable are those plasticisers which are considered harmless under food regulations.

The adhesives can also comprise solvents. They are the conventional solvents, which are able to evaporate at temperatures up to 120° C. The solvents can be selected from the group of the aliphatic hydrocarbons, aromatic hydrocarbons, ketones or esters of in particular C2-C6-carboxylic acids. In another preferred embodiment, the 2K adhesive is solvent-free. It is thereby possible to ensure in particular by the composition of component A and component B that a low-viscosity mixture of component A and B is obtained at temperatures up to 50° C.

A PU adhesive that is used consists of a component A, which comprises reactive NCO groups, a component B, which comprises reactive NH or in particular OH groups. Components A and B can additionally comprise from 0 to 30% additives and auxiliary substances. The additives can in principle be present in both components. However, it must be ensured that additives having NCO-reactive groups are preferably present in the OH component. Otherwise, the storage stability of the products is reduced.

Components A and components B are individually storage-stable. The two components are mixed for use in such a manner that an approximately equal equivalent ratio of OH groups to NCO groups is obtained. The mixing ratio of the adhesives is specified. It can be from 1:10 to 10:1 (based on volume), in particular from 1:2 to 2:1.

The 2K PU adhesives which can be used are to have a low viscosity at the application temperature of approximately from 20 to 80° C. The viscosity of the 2K PU adhesives according to the invention, measured immediately after the constituents have been mixed, is to be from 200 to 10,000 mPas at the application temperature, preferably from 500 to 5000 mPas (at from 20 to 60° C., Brookfield viscometer, EN ISO 2555). A higher application temperature may be possible, but it must be noted that the film substrates to be bonded may be temperature-sensitive.

By means of the process, a suitable adhesive is applied as a layer to a substrate. The adhesive is to be applied in a layer thickness of from 1 g/m² to 100 g/m², preferably from 1 to 30 g/m², in particular less than 20 g/m².

Further suitable adhesives can be physically bonding or chemically curing adhesives. The physically bonding adhesives are preferably dispersion adhesives, hot melt adhesives, contact adhesives or plastisols. The chemically curing adhesives are preferably cyanoacrylate, methyl (meth)acrylate, anaerobically-curing, radiation-curing, phenol-formaldehyde resin, silicone-based, silane-crosslinking, epoxy-resin-based, polyurethane and pressure sensitive adhesives.

### Layer E)

Layer E) provided according to the invention is selected from a thermoplastic plastic.

Thermoplastic plastics for the substrate layer are preferably polycarbonate, copolycarbonate, polyester carbonate, polystyrene, styrene copolymers, aromatic polyesters such as polyethylene terephthalate (PET), PET-cyclohexanedimethanol copolymer (PETG), polyethylene naphthalate (PEN), polybutylene terephthalate (PBT), aliphatic polyolefins such as polypropylene or polyethylene, cyclic polyolefin, poly- or copoly-acrylates and poly- or copoly-methacrylate such as, for example, poly- or copoly-methyl methacrylates (such as PMMA) and also copolymers with styrene such as, for example, transparent polystyrene-acrylonitrile (PSAN), thermoplastic polyurethanes, polymers based on cyclic olefins (e.g. TOPAS®, a commercial product from Ticona), polycarbonate blends with olefinic copolymers or graft polymers, such as, for example, styrene/acrylonitrile copolymers. Polycarbonate, copolycarbonate, polyester carbonate, aliphatic polyolefins such as polypropylene or polyethylene, cyclic polyolefin, PET or PETG are particularly preferred. The substrate layer is most particularly preferably made of polycarbonate.

The above-mentioned polymers can be used on their own or in mixtures.

Polycarbonates within the meaning of the present invention are homopolycarbonates, copolycarbonates and polyester carbonates as are described, for example, in EP-A-1,657,281.

The preparation of aromatic polycarbonates is carried out, for example, by reacting diphenols with carbonic acid halides, preferably phosgene, and/or with aromatic dicarboxylic acid dihalides, preferably benzenedicarboxylic acid dihalides, by the interfacial process, optionally using chain terminators, for example monophenols, and optionally using branching agents having a functionality of three or more than three, for example triphenols or tetraphenols. Preparation by a melt polymerisation process by reacting diphenols with, for example, diphenyl carbonate is also possible.

Diphenols for the preparation of the aromatic polycarbonates and/or aromatic polyester carbonates are preferably those of formula (I)

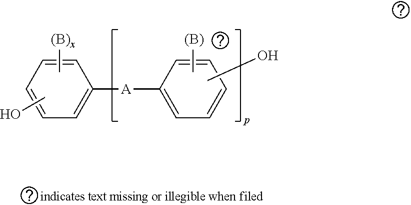

wherein
A denotes a single bond, C1- to C5-alkylene, C2- to C5-alkylidene, C5- to C6-cycloalkylidene, —O—, —SO—, —CO—, —S—, —SO₂—, C6- to C12-arylene, to which further aromatic rings optionally containing heteroatoms can be fused,
or a radical of formula (II) or (III)

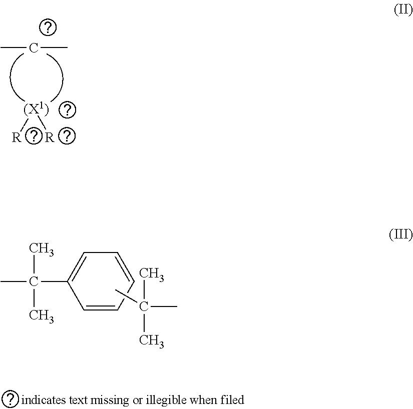

B in each case denotes C1- to C12-alkyl, preferably methyl, halogen, preferably chlorine and/or bromine,
x in each case independently of one another denote 0, 1 or 2,
p are 1 or 0, and
R5 and R6 can be chosen individually for each X1 and independently of one another denote hydrogen or C1- to C6-alkyl, preferably hydrogen, methyl or ethyl,
X1 denotes carbon, and
m denotes an integer from 4 to 7, preferably 4 or 5, with the proviso that on at least one atom X1, R5 and R6 are simultaneously alkyl.

Diphenols suitable for the preparation of the polycarbonates are, for example, hydroquinone, resorcinol, dihydroxydiphenyls, bis-(hydroxyphenyl)-alkanes, bis(hydroxyphenyl)-cycloalkanes, bis-(hydroxyphenyl) sulfides, bis-(hydroxyphenyl) ethers, bis-(hydroxyphenyl) ketones, bis-(hydroxyphenyl)-sulfones, bis-(hydroxyphenyl) sulfoxides, alpha-alpha′-bis-(hydroxyphenyl)-diisopropylbenzenes, phthalimidines derived from isatin or phenolphthalein derivatives, as well as compounds thereof alkylated and halogenated on the ring.

Preferred diphenols are 4,4′-dihydroxydiphenyl, 2,2-bis-(4-hydroxyphenyl)-propane, 2,4-bis-(4-hydroxyphenyl)-2-methylbutane, 1,1-bis-(4-hydroxyphenyl)-p-diisopropylbenzene, 2,2-bis-(3-methyl-4-hydroxyphenyl)-propane, 2,2-bis-(3-chloro-4-hydroxyphenyl)-propane, bis-(3,5-dimethyl-4-hydroxyphenyl)-methane, 2,2-bis-(3,5-dimethyl-4-hydroxyphenyl)-propane, bis-(3,5-dimethyl-4-hydroxyphenyl)-sulfone, 2,4-bis-(3,5-dimethyl-4-hydroxyphenyl)-2-methylbutane, 1,1-bis-(3,5-dimethyl-4-hydroxyphenyl)-p-diisopropylbenzene, 2,2-bis-(3,5-dichloro-4-hydroxyphenyl)-propane, 2,2-bis-(3,5-dibromo-4-hydroxyphenyl)-propane, 1,1-bis-(4-hydroxyphenyl)-3,3,5-trimethylcyclohexane, and 2-hydrocarbyl-3,3-bis(4-hydroxyaryl)phthalimidines, and the reaction product of N-phenylisatin and phenol.

Particularly preferred diphenols are 2,2-bis-(4-hydroxyphenyl)-propane, 2,2-bis-(3,5-dimethyl-4-hydroxyphenyl)-propane, 2,2-bis-(3,5-dichloro-4-hydroxyphenyl)-propane, 2,2-bis-(3,5-dibromo-4-hydroxyphenyl)-propane, 1,1-bis-(4-hydroxyphenyl)-cyclohexane and 1,1-bis-(4-hydroxyphenyl)-3,3,5-trimethylcyclohexane.

In the case of the homopolycarbonates, only one diphenol is used; in the case of the copolycarbonates, a plurality of diphenols is used. Suitable carbonic acid derivatives are, for example, phosgene or diphenyl carbonate.

Suitable chain terminators which can be used in the preparation of the polycarbonates are both monophenols and monocarboxylic acids. Suitable monophenols are phenol itself, alkylphenols such as cresols, p-tert-butylphenol, cumylphenol, p-n-octylphenol, p-isooctylphenol, p-n-nonylphenol and p-isononylphenol, halophenols such as p-chlorophenol, 2,4-dichlorophenol, p-bromophenol and 2,4,6-tribromophenol, 2,4,6-triiodophenol, p-iodophenol and mixtures thereof. Preferred chain terminators are phenol, cumylphenol and/or p-tert-butylphenol.

Particularly preferred polycarbonates within the scope of the present invention are homopolycarbonates based on bisphenol A and copolycarbonates based on monomers selected from at least one of the group comprising bisphenol A, 1,1-bis-(4-hydroxyphenyl)-3,3,5-trimethylcyclohexane, 2-hydrocarbyl-3,3-bis(4-hydroxyaryl)phthalimidines and the reaction products of N-phenylisatin and phenol. The polycarbonates can in a known manner be linear or branched. The proportion of comonomers, based on bisphenol A, is generally up to 60 wt. %, preferably up to 50 wt. %, particularly preferably from 3 to 30 wt. %. Mixtures of homopolycarbonate and copolycarbonates can likewise be used.

Polycarbonates and copolycarbonates containing 2-hydrocarbyl-3,3-bis(4-hydroxyaryl)phthalimidines as monomers are known inter alia from EP 1 582 549 A1. Polycarbonates and copolycarbonates containing bisphenol monomers based on reaction products of N-phenylisatin and phenol are described, for example, in WO 2008/037364 A1.

The thermoplastic, aromatic polycarbonates have mean molecular weights (weight average Mw, measured by GPC (gel permeation chromatography) with polycarbonate standard) of from 10,000 to 80,000 g/mol, preferably from 14,000 to 32,000 g/mol, particularly preferably from 18,000 to 32,000 g/mol. In the case of injection-moulded polycarbonate mouldings, the preferred mean molecular weight is from 20,000 to 29,000 g/mol. In the case of extruded polycarbonate mouldings, the preferred mean molecular weight is from 25,000 to 32,000 g/mol.

The thermoplastic plastics according to the invention can further comprise fillers. In the present invention, fillers have the function of reducing the coefficient of thermal expansion of the polycarbonate and regulating, preferably reducing, the permeability of gases and water vapour.

Suitable fillers are glass beads, hollow glass beads, glass flakes, carbon blacks, graphite, carbon nanotubes, quartz, talc, mica, silicates, nitrides, wollastonite, as well as pyrogenic or precipitated silicas, wherein the silicas have BET surface areas of at least 50 m²/g (according to DIN 66131/2).

Preferred fibrous fillers are metal fibres, carbon fibres, plastics fibres, glass fibres or ground glass fibres, with glass fibres or ground glass fibres being particularly preferred. Preferred glass fibres are also those which are used in the form of endless fibres (rovings), long glass fibres and chopped glass fibres, which are produced from M-, E-, A-, S-, R- or C-glass, with E-, A- or C-glass being further preferred.

The diameter of the fibres is preferably from 5 to 25 μm, more preferably from 6 to 20 μm, particularly preferably from 7 to 15 μm. Long glass fibres have a length of preferably from 5 to 50 mm, more preferably from 5 to 30 mm, yet more preferably from 6 to 15 mm, and particularly preferably from 7 to 12 mm; they are described, for example, in WO-A 2006/040087. The chopped glass fibres preferably comprise at least 70 wt. % glass fibres having a length of more than 60 μm.

Further inorganic fillers are inorganic particles having a particle shape selected from the group comprising spherical/cubic, tabular/discus-shaped and plate-like geometries. Particularly suitable are inorganic fillers with spherical or plate-like geometry, preferably in finely divided and/or porous form with a large external and/or internal surface area. They are preferably thermally inert inorganic materials based in particular on nitrides such as boron nitride, oxides or mixed oxides such as cerium oxide, aluminium oxide, carbides such as tungsten carbide, silicon carbide or boron carbide, powdered quartz such as quartz flour, amorphous SiO₂, ground sand, glass particles such as glass powders, in particular glass beads, silicates or aluminosilicates, graphite, in particular highly pure, synthetic graphite. Particular preference is given to quartz and talc, most preferably quartz (spherical particle shape). These fillers are characterised by a mean diameter d50% of from 0.1 to 10 μm, preferably from 0.2 to 8.0 μm, more preferably from 0.5 to 5 μm.

Silicates are characterised by a mean diameter d50 of from 2 to 10 μm, preferably from 2.5 to 8.0 μm, more preferably from 3 to 5 μm, and particularly preferably of 3 μm, wherein preference is given to an upper diameter d95% of correspondingly from 6 to 34 μm, more preferably from 6.5 to 25.0 μm, yet more preferably from 7 to 15 μm, and particularly preferably of 10 μm. The silicates preferably have a specific BET surface area, determined by nitrogen adsorption according to ISO 9277, of from 0.4 to 8.0 m²/g, more preferably from 2 to 6 m²/g, and particularly preferably from 4.4 to 5.0 m²/g.

Further preferred silicates comprise a maximum of only 3 wt. % minor constituents, preferably with the following contents:

### Al₂O₃<2.0 wt. %,

### Fe₂O₃<0.05 wt. %,

### (CaO+MgO)<0.1 wt. %,

(Na₂O+K₂O)<0.1 wt. %, in each case based on the total weight of the silicate.

A further advantageous embodiment uses wollastonite or talc in the form of finely ground types having a mean particle diameter d50 of <10 μm, preferably <5 μm, particularly preferably <2 μm, most particularly preferably <1.5 μm. The particle size distribution is determined by air classification.

The silicates can have a coating of organosilicon compounds, wherein epoxysilane, methylsiloxane and methacrylsilane sizes are preferably used. An epoxysilane size is particularly preferred.

The fillers can be added in an amount of up to 40 wt. %, based on the amount of polycarbonate. Preference is given to from 2.0 to 40.0 wt. %, preferably from 3.0 to 30.0 wt. %, more preferably from 5.0 to 20.0 wt. %, and particularly preferably from 7.0 to 14.0 wt. %.

Suitable blend partners for the thermoplastic plastics according to the invention, in particular for polycarbonates, are graft polymers of vinyl monomers on graft bases such as diene rubbers or acrylate rubbers. Graft polymers B are preferably those of

B.1 from 5 to 95 wt. %, preferably from 30 to 90 wt. %, of at least one vinyl monomer on
B.2 from 95 to 5 wt. %, preferably from 70 to 10 wt. %, of one or more graft bases having glass transition temperatures <10° C., preferably <0° C., particularly preferably <−20° C.

The graft base B.2 generally has a mean particle size (d50 value) of from 0.05 to 10 μm, preferably from 0.1 to 5 μm, particularly preferably from 0.2 to 1 μm.

Monomers B.1 are preferably mixtures of

B.1.1 from 50 to 99 parts by weight of vinyl aromatic compounds and/or vinyl aromatic compounds substituted on the ring (such as styrene, *-methylstyrene, p-methylstyrene, p-chlorostyrene) and/or methacrylic acid (C1-C8)-alkyl esters (such as methyl methacrylate, ethyl methacrylate), and
B.1.2 from 1 to 50 parts by weight of vinyl cyanides (unsaturated nitriles such as acrylonitrile and methacrylonitrile) and/or (meth)acrylic acid (C1-C8)-alkyl esters, such as methyl methacrylate, n-butyl acrylate, tert-butyl acrylate, and/or derivatives (such as anhydrides and imides) of unsaturated carboxylic acids, for example maleic anhydride and N-phenyl-maleimide.

Preferred monomers B.1.1 are selected from at least one of the monomers styrene, *-methylstyrene and methyl methacrylate; preferred monomers B.1.2 are selected from at least one of the monomers acrylonitrile, maleic anhydride and methyl methacrylate. Particularly preferred monomers are B.1.1 styrene and B.1.2 acrylonitrile.

Graft bases B.2 suitable for the graft polymers B are, for example, diene rubbers, EP(D)M rubbers, that is to say those based on ethylene/propylene and optionally diene, acrylate, polyurethane, silicone, chloroprene and ethylene/vinyl acetate rubbers.

Preferred graft bases B.2 are diene rubbers, for example based on butadiene and isoprene, or mixtures of diene rubbers or copolymers of diene rubbers or mixtures thereof with further copolymerisable monomers (e.g. according to B.1.1 and B.1.2), with the proviso that the glass transition temperature of component B.2 is below <10° C., preferably <0° C., particularly preferably <10° C. Pure polybutadiene rubber is particularly preferred.

Particularly preferred polymers B are, for example, ABS polymers (emulsion, mass and suspension ABS), as are described, for example, in DE-OS 2 035 390 (=U.S. Pat. No. 3,644,574) or in DE-OS 2 248 242 (=GB-PS 1 409 275) or in Ullmanns, Enzyklopadie der Technischen Chemie, Vol. 19 (1980), p. 280 ff. The gel content of the graft base B.2 is at least 30 wt. %, preferably at least 40 wt. % (measured in toluene).

The graft copolymers B are prepared by radical polymerisation, for example by emulsion, suspension, solution or mass polymerisation, preferably by emulsion or mass polymerisation.

Because, as is known, the graft monomers are not necessarily grafted completely onto the graft base in the graft reaction, graft polymers B are also to be understood according to the invention as being products that are obtained by (co)polymerisation of the graft monomers in the presence of the graft base and are also obtained during working up.

The polymer compositions can optionally also comprise further conventional polymer additives, such as, for example, the antioxidants, heat stabilisers, demoulding agents, optical brighteners, UV absorbers and light scattering agents described in EP-A 0 839 623, WO-A 96/15102, EP-A 0 500 496 or “Plastics Additives Handbook”, Hans Zweifel, 5th Edition 2000, Hanser Verlag, Munich, in the amounts conventional for the thermoplastics in question.

The substrate layer E) can further be a coextruded layer of different or identical thermoplastics, for example polycarbonate/PMMA, polycarbonate/PVDF or polycarbonate/PTFE, but also polycarbonate/polycarbonate.

Suitable UV stabilisers are benzotriazoles, triazines, benzophenones and/or arylated cyanoacrylates. Particularly suitable UV absorbers are hydroxybenzotriazoles, such as 2-(3′,5′-bis-(1,1-dimethylbenzyl)-2′-hydroxy-phenyl)-benzotriazole (Tinuvin® 234, Ciba Spezialitätenchemie, Basel), 2-(2′-hydroxy-5′-(tert-octyl)-phenyl)-benzotriazole (Tinuvin® 329, Ciba Spezialitätenchemie, Basel), 2-(2′-hydroxy-3′-(2-butyl)-5′-(tert-butyl)-phenyl-benzotriazole (Tinuvin® 350, Ciba Spezialitätenchemie, Basel), bis-(3-(2H-benztriazolyl)-2-hydroxy-5-tert-octyl)methane (Tinuvin® 360, Ciba Spezialitätenchemie, Basel), (2-(4,6-diphenyl-1,3,5-triazin-2-yl)-5-(hexyloxy)-phenol (Tinuvin® 1577, Ciba Spezialitätenchemie, Basel) and also the benzophenones 2,4-dihydroxy-benzophenone (Chimasorb® 22, Ciba Spezialitätenchemie, Basel) and 2-hydroxy-4-(octyloxy)-benzophenone (Chimassorb® 81, Ciba, Basel), 2-propenoic acid, 2-cyano-3,3-diphenyl-2,2-bis-[[(2-cyano-1-oxo-3,3-diphenyl-2-propenyl)oxy]-methyl]-1,3-propanediyl ester (9CI) (Uvinul® 3030, BASF AG Ludwigshafen), 2-[2-hydroxy-4-(2-ethylhexyl)oxy]phenyl-4,6-di(4-phenyl)phenyl-1,3,5-triazine (CGX UVA 006, Ciba Spezialitätenchemie, Basel) or tetraethyl 2,2′-(1,4-phenylene-dimethylidene)-bismalonate (Hostavin® B-Cap, Clariant AG).

The composition of the thermoplastic plastics can comprise UV absorbers conventionally in an amount of from 0 to 10 wt. %, preferably from 0.001 wt. % to 7.000 wt. %, particularly preferably from 0.001 wt. % to 5.000 wt. %, based on the total composition.

The preparation of the compositions of the thermoplastic plastics is carried out by conventional methods of incorporation, by combining, mixing and homogenising the individual constituents, the homogenisation in particular preferably taking place in the melt under the action of shear forces. Combining and mixing before the melt homogenisation optionally take place using powder premixtures.

The substrate material can be in the form of a film or a sheet. The film can be shaped and back injection moulded with a further thermoplastic from the above-mentioned thermoplastics (film insert moulding (FIM)). Sheets can be thermoformed or processed by means of drape forming or bent while cold. Shaping by injection moulding processes is also possible. These processes are known to the person skilled in the art.

The thickness of the substrate layer must be such that sufficient rigidity is ensured in the component. In the case of a film, the substrate layer E) can be reinforced by back injection moulding in order to ensure sufficient rigidity.

The total thickness of layer E), that is to say including possible back injection moulding or coextruded layers, is generally from 0.5 mm to 10 mm. Particularly preferably, the thickness of layer E is from 0.8 mm to 8 mm, from 1 mm to 4 mm, from 2 mm to 3 mm. The indicated thicknesses relate in particular to the total substrate thickness when using polycarbonate as substrate material, including possible back injection moulding or coextruded layers.

In a preferred embodiment, layer B) is deposited directly on the substrate E).

In a further preferred embodiment of the present invention, layer B) is deposited on a carrier film C) and then the combination of layer B) and C) is joined via an adhesive layer D) to the substrate E.

Layer A) is adhesively bonded with the adhesive layer contained in layer A) to the preferred layer sequences BE and BCDE in each case to the layer B).

### Use

The multilayer structure according to the invention can be used as a reflector for photovoltaic modules (concentrating photovoltaics) and solar modules (concentrating solar power), within the context of lighting systems, preference being given to systems that use LEDs as illuminants, as mirrors in the residential sector and in the automotive sector (e.g. aircraft and railway vehicles, buses, commercial vehicles and cars), reflectors in fibre-optic systems. The present invention therefore also provides photovoltaic modules and solar modules, lighting systems comprising a multilayer structure according to the invention.

The invention is explained in greater detail by means of the following examples, without implying any limitation. The examples according to the invention merely represent preferred embodiments of the present invention.

### EXAMPLES

As layer A) there is used Solar Mirror Film 1100 from 3M.

As layer E) there is used a polycarbonate sheet (Makrolon® UV clear 2099 from Bayer MaterialScience GmbH), produced by extrusion with a sheet thickness of 3 mm.

### Example 1

### According to the Invention

Deposition of an SiOₓ Layer (Layer B) on polycarbonate Sheet (Layer E)

The SiOₓ layer was deposited by means of reactive vapour deposition. The specimens were placed into the vacuum chamber and evacuated to a final vacuum of p<1*10⁻⁵ mbar. The specimens were located on a rotating specimen plate throughout the entire process phase. The specimens rotated at about 20 rpm above the coating sources. The specimens were first pretreated by means of a DC plasma discharge. To that end, an Ar plasma was ignited for 1 minute at about 400 W at p=0.1 mbar. This was followed by a further evacuation phase to p<1*10⁻⁵ mbar, and then the actual coating of the SiOₓ layer. In this process step, SiO was evaporated from a carbon crucible with the aid of an electron beam evaporator. The process pressure at a flow of oxygen of 1.3 l/h was p=2*10⁻⁴ to 5*10⁻⁴ mbar. The source-substrate distance was 520 mm. The power was so adjusted that a rate of 5-10 Angstrom's, measured with a quartz crystal microbalance, was obtained. The layer was deposited in a time of 105 s. The layer thickness was 100 nm, measured by means of a quartz crystal microbalance.

### Example 2

### According to the Invention

Deposition of an Al₂O₃ Layer (Layer B) on polycarbonate Sheet (Layer E)

The layer was deposited by means of pulsed DC reactive sputtering. The specimens were placed into the vacuum chamber and evacuated to a final vacuum of p<1*10⁻⁵ mbar. The specimens were located on a rotating specimen plate throughout the entire process phase. The specimens rotated at about 20 rpm above the coating sources. The specimens were first pretreated by means of a mid-frequency plasma discharge (f=40 KHz). To that end, an Ar plasma was ignited for 1 minute at 500 W at p=0.1 mbar. This was followed by a further evacuation phase to p<1*10⁻⁵ mbar, and then the actual coating of the AlOₓ layer. The layer was deposited from an Al target by means of reactive, pulsed DC sputtering with a pulse frequency of 150 kHz. The coating source used was a round planar magnetron ION′X-8″HV from Thin Film Consulting with a diameter of 200 mm, which was operated with an Advanced Energy “Pinnacle™ Plus+5 kW” generator. The target was first presputtered for 1 minute with the shutter closed, and then the AlOₓ layer was deposited on the silver layer with the shutter open within a period of 8 minutes 20 seconds at 340 V in voltage regulation mode and at a total pressure of p=5·10⁻³ mbar. The O₂/Ar ratio was adjusted to 8%. A layer thickness of 170 nm was found by means of a surface profiler as described below. The substrate-coating source distance was always 80 mm.

### Adjustment of the Layer Thicknesses:

In order to adjust the layer thicknesses, a calibration of the process parameters was first carried out. To that end, different layer thicknesses were deposited with defined process parameters on a microscope slide which was provided with an adhesive strip in the middle in order to create a step. After deposition of the layer in question, the adhesive strip was removed and the height of the resulting step was determined by means of a KLA Tencor Alpha-Step 500 surface profiler from Tencor Instruments.

Process parameters which must be set in order to produce the desired target layer thicknesses are thereby determined.

### Example 3

### According to the Invention

### Deposition of an Aluminium Layer (Layer B) on Polycarbonate Sheet (Layer E)

Production process: The layer was deposited by means of DC sputtering. The PC sheet was first introduced into the vacuum chamber and evacuated to p<2·10⁻⁵ mbar. Plasma pretreatment was then carried out: The PC sheet was pretreated for 1 minute at 500 W and 0.1 mbar Ar in mid-frequency plasma (40 kHz). The aluminium layer was deposited by means of DC sputtering. The coating source used was a round planar magnetron ION′X-8″HV from Thin Film Consulting with a diameter of 200 mm, which was operated with a “Pinnacle™ Plus+5 kW” generator from Advanced Energy. The target (here: aluminium) was first presputtered for 2 minutes with the shutter closed, and then the Al layer was deposited with the shutter open within a period of 130 seconds at 2000 W and a pressure of p=5·10⁻³ mbar. The specimens were rotated above the coating sources at about 20 rpm during all the coating steps in order to increase the homogeneity of the coating. The substrate-coating source distance was always 80 mm. The resulting layer thickness of the aluminium layer on the substrate was 145 nm.

### Example 4

### Comparison Example

Deposition of an SiO₂ layer (layer B), which was produced by a sol-gel process, which is described in greater detail, for example, in U.S. Pat. No. 4,410,594 and U.S. Pat. No. 5,041,313, on polycarbonate sheet (layer E). Such coating agents are obtainable commercially from Momentive Performance Materials as combinations of primer SHP401 and topcoat AS4000.

Application of the coating agent SHP401 by flooding was carried out at a temperature of 23° C. and 37% relative humidity by flooding onto a polycarbonate sheet. The sheet so coated was stored suspended for 30 minutes at a temperature of 23° C. and 37% relative humidity. Application of the coating agent AS4000 was then carried out by flooding at a temperature of 23° C. and 37% relative humidity by flooding. The sheet so coated was stored suspended for 30 minutes at a temperature of 23° C. and 37% relative humidity. Finally, the coatings on the sheet were cured in a circulating-air drying cabinet for 60 minutes at a temperature of 130° C.

### Example 5

### Comparison Example

### Polycarbonate Sheet (Layer E) without Surface Modification (Layer B)

This is a polycarbonate solid sheet (Makrolon® UV clear 2099 from Bayer MaterialScience GmbH), produced by extrusion with a sheet thickness of 3 mm.

### Example 6

### According to the Invention

### Incorporation of an SiOₓ Barrier Layer (Layer B) by Lamination on Polycarbonate Sheet (Layer E)

An SiOₓ layer (layer B) on a 50 μm thick PET film (layer C), used in the form of the product CERAMIS CTXA50 from Amcor, was joined with the aid of a 2-component adhesive Liofol LA 8192-22/LA 7394 (mixing ratio of polyol to isocyanate-based curing agent 1:1, layer D) from Henkel to a polycarbonate sheet (layer E).

Layer A) was joined, using the adhesive layer contained in layer A), to Examples 1 to 6 so prepared, in such a manner that no air inclusions were detectable between layer A) and the underlying structure according to Examples 1 to 6. The structures according to Examples 1 to 6 were so placed that layer E), except in the case of Example 5, does not come into contact with layer A). To that end, layer A) was held in an oblique position with one edge on the structures according to Examples 1 to 6. Layer A was then slowly rolled under pressure onto the structures according to Examples 1 to 6 using a commercially available rubber roller. Enclosed air bubbles were pushed to the edge of the composite with the commercially available rubber roller, where the enclosed air bubbles were able to escape.

The laminates were sealed circumferentially at the edge using S53L10M adhesive tape from Stokvis Deutschland GmbH.

In order to simulate outside influences, the laminates sealed at the edge were exposed in a Vötsch climate testing cabinet VC³ 7018 to different climate tests, which are described below.

TABLE 1

| Test | Conditions |
|---|---|
| Alternating | 400 cycles of temperature change |
| climate test (DIN | from −40° C. to 65° C. without humidity |
| EN 62108 10.6 & 10.8) | (14 cycles per day) followed by |
| | 40 cycles of humidity-frost test |
| | (20 h at 85° C./85% relative humidity followed |
| | by 4 h cooling to −40° C. and then heating |
| | again to 85° C./85% relative humidity) |
| Damp-heat test | 2000 hours 65° C. at 85% relative humidity |
| (DIN EN 62018 10.7) | |

After these stresses, the laminates were assessed visually for blistering. The assessment is summarised in the following table. Laminates in which blistering occurred consequently also exhibited poorer adhesion of layer A to the surface-modified substrate.

TABLE 2

| Example | Alternating climate test | Damp-heat test |
|---|---|---|
| 1 | no blistering | no blistering |
| 2 | no blistering | no blistering |
| 3 | no blistering | no blistering |
| 4 | pronounced blistering after 200 | pronounced blistering after |
| | cycles | 1000 hours |
| 5 | pronounced blistering | not tested |
| 6 | no blistering | no blistering |

### Result

Examples 1 to 3 clearly show that purposive surface modification of the polycarbonate sheets (layer E) is necessary for the adhesive bonding of films (layer A) with an adhesive layer (contained in layer A). The absence (Example 5) or even incorrect surface modification (Example 4) results in the increased occurrence of blisters after the described stresses and accordingly to a limited use of these laminates. The introduction of the surface modification can also take place by lamination of a corresponding combination of layers B, C and D (Example 6).

1.-12. (canceled)

13. A multilayer structure comprising:
(A) a functional film comprising:
a VIS/IR-reflecting metal layer on a carrier film, wherein the carrier film comprises a single-layer, or a UV- and/or UV/VIS-reflecting multi-ply layer; at least one adhesive layer, wherein the adhesive layer comprises a pressure sensitive adhesive; and optionally at least one scratch-resistant layer;
(B) a functional layer comprising a layer selected from at least one of the group consisting of metal nitrides, metal oxides, semimetal oxides, mixed oxides and metals, wherein the layer optionally comprises a coating;
(C) optionally a carrier film;
(D) optionally an adhesive layer; and
(E) a thermoplastic substrate layer.

14. The multilayer structure according to claim 13, wherein the VIS/IR-reflecting metal layer of the functional film (A) comprises aluminium, silver and/or copper.

15. The multilayer structure according to claim 14, wherein the functional film (A) comprises silver and/or copper.

16. The multilayer structure according to claim 14, wherein the adhesive in layer (A) is a pressure sensitive adhesive selected from the group consisting of acrylates, polyurethanes, polyureas, polyalphaolefins, silicones, natural rubber and synthetic rubber.

17. The multilayer structure according to claim 16, wherein the pressure sensitive adhesive is selected from the group consisting of acrylates, polyurethanes and polyureas.

18. The multilayer structure according to claim 16, wherein the functional layer (B) comprises aluminium, copper, silver, titanium, chromium, chromium alloys, stainless steel, gold, platinum, aluminium oxide, titanium dioxide, silicon oxide SiOₓ, tantalum pentoxide Ta₂O₅, zirconium oxide, zirconium dioxide, Nb₂O₅, HfO, zinc-tin oxide, indium-tin oxide, aluminium-zinc oxide, silicon nitride, boron nitride or titanium nitride.

19. The multilayer structure according to claim 18, wherein the functional layer (B) comprises aluminium, stainless steel, copper, titanium, aluminium oxide, silicon oxide SiOₓ, silicon nitride or zinc-tin oxide.

20. The multilayer structure according to claim 18, wherein the thickness of the layer of metal nitrides, metal oxides, semimetal oxides, mixed oxides or metals within the functional layer (B) is from 5 nm to 300 nm.

21. The multilayer structure according to claim 20, wherein the thickness of the layer of metal nitrides, metal oxides, semimetal oxides, mixed oxides or metals within the functional layer (B) is from 10 nm to 200 nm.

22. The multilayer structure according to claim 21, wherein the thickness of the layer of metal nitrides, metal oxides, semimetal oxides, mixed oxides or metals within the functional layer (B) is from 20 nm to 180 nm.

23. The multilayer structure according to claim 13, wherein the multilayer structure comprises a carrier film (C) comprising a thermoplastic plastic selected from the group consisting of polymethacrylates, polyethylene terephthalate, polyethylene terephthalate-cyclohexanedimethanol copolymer, polyethylene naphthalate, polycarbonate, copolycarbonate or polyester carbonate.

24. The multilayer structure according to claim 23, wherein the multilayer structure comprises an adhesive layer (D) comprising dispersion adhesives, hot melt adhesives, contact adhesives, plastisols, cyanoacrylates, methyl (meth)acrylates, anerobically curing phenol-formaldehyde resins, radiation-curing phenol-formaldehyde resins, silicones, silane-crosslinking polymer adhesives, epoxy resins, polyurethanes and pressure sensitive adhesives.

25. The multilayer structure according to claim 24, wherein adhesive layer (D) comprises hot melt adhesives or polyurethanes.

26. The multilayer structure according to claim 13, wherein the substrate layer (E) comprises a thermoplastic plastic.

27. The multilayer structure according to claim 26, wherein the thermoplastic plastic is a polycarbonate, a copolycarbonate, a polyester carbonate, an aliphatic polyolefin, a cyclic polyolefin, a polyethylene terephthalate or a cyclohexanedimethanol copolymer.

28. The multilayer structure according to claim 27, wherein the thermoplastic plastic is a polycarbonate.

29. The multilayer structure according to claim 13, wherein layer (B) has been applied by a vacuum deposition process to film (C) or layer (E).

30. A process for the production of a multilayer structure according to claim 13, wherein:
I. layer (B) is applied by a vacuum deposition process to film (C) or layer (E), or
II. in the case of a multilayer structure comprising film (A), layer (B), film (C), layer (D) and layer (E):
a) film (A), layer (B) and film (C) are applied by application of adhesive layer (D) to substrate layer (E), or
b) layer (B) is applied to film (C), and the film so obtained by application of layer (B) to film (C) is applied by application of adhesive layer (D) to substrate layer (E), and film (A) is then applied.

31. Use of a multilayer structure according to claim 13 as a reflector for photovoltaic modules, a solar modules, lighting systems, as a mirror in the residential sector and in the automotive sector including aircraft and railway vehicles, buses, commercial vehicles and cars, and in fibre-optic systems.

32. A reflector for photovoltaic modules, solar modules, lighting systems, residential mirrors, or automotive mirrors comprising a multilayer structure according to claim 13.
